(19) United States
(12) Patent Application Publication
(10) Pub. No.: US 2024/0397592 A1
(43) Pub. Date: Nov. 28, 2024

(54) COOKING APPLIANCE

(71) Applicant: LG ELECTRONICS INC., Seoul (KR)

(72) Inventors: Sunghun SIM, Seoul (KR); Jaekyung YANG, Seoul (KR); Junghyeong HA, Seoul (KR); Myeongjun SHIN, Seoul (KR)

(73) Assignee: LG ELECTRONICS INC., Seoul (KR)

(21) Appl. No.: 18/674,460

(22) Filed: May 24, 2024

(30) Foreign Application Priority Data
May 26, 2023 (KR) 10-2023-0068505

(51) Int. Cl. H05B 6/76; F24C 15/02; H05B 6/64

(52) U.S. Cl. CPC H05B 6/76; F24C 15/02; H05B 6/6414

(57) ABSTRACT

A cooking appliance includes a cooking chamber configured to receive a load to be heated, a front panel disposed at one end of the cooking chamber and having a bent portion, and a door configured to shield both heat and electromagnetic waves generated in the cooking chamber. The door includes a door frame including a choke and a choke cover. A shielding member is disposed between the front panel and the door. The shielding member is in contact with at least one surface of the front panel and in contact with the door.

### CROSS-REFERENCE TO RELATED APPLICATIONS

The present application claims priority under 35 U.S.C. 119 to Korean Patent Application No. 10-2023-0068505 filed in the Republic of Korea, on May 26, 2023, the entirety of which is hereby incorporated by reference into the present application.

### BACKGROUND

The present disclosure relates to a cooking appliance.

Various types of cooking appliances are used to heat food at home or in the restaurant. For example, various cooking appliances such as microwave ovens, induction heating type electric stoves, and grill heaters are used.

A microwave oven is a high-frequency heating type cooking appliance that uses molecules in a high-frequency electric field to vibrate violently and generate heat, allowing food to be heated evenly in a short period of time.

An induction heating type electric stove is a cooking appliance that heats an object to be heated by using electromagnetic induction. Specifically, when high-frequency power of a predetermined magnitude is applied to a coil, the induction heating type electric stove generates an eddy current in the object to be heated consisting of a metal component using a magnetic field generated around the coil to heat the object to be heated itself.

A grill heater is a cooking appliance that heats food by radiating or convecting infrared heat. Because the infrared heat penetrates through food, the food may be heated evenly as a whole.

In the case of a built-in combination oven, compared to a microwave oven, a door gap is 2-3 times larger. Therefore, according to the related art, a plurality of door chokes have been used to reliably shield electromagnetic wave leakage. This may cause problems in the manufacturing process and size management because the door becomes thicker or the structural configuration becomes more complex and costly to manufacture.

### SUMMARY OF THE DISCLOSURE

The present disclosure provides a cooking appliance including a door with a single door choke to block electromagnetic waves as well as heat.

The present disclosure provides a cooking appliance that achieves both heat and electromagnetic shielding through the structural design of a gasket and a door choke.

A cooking appliance according to an embodiment of the present disclosure can include a cooking chamber where a load is located, a front panel located at one end of the cooking chamber and having a bent portion, and a door having a structure that shields heat and electromagnetic waves generated in the cooking chamber, in which the door includes a door frame including a choke and a choke cover, a shielding member is disposed between the front panel and the door, and the shielding member is in contact with at least one surface of the front panel and the door.

In the cooking appliance according to an embodiment of the present disclosure, the door frame can include a door gap protruding toward the cooking chamber.

In the cooking appliance according to an embodiment of the present disclosure, the shielding member can be formed of a circular, clastic material, and an outer circumference of the shielding member can be covered with a metal mesh.

In the cooking appliance according to an embodiment of the present disclosure, a height and a length of the door gap can be associated with at least one of a size or elasticity of the shielding member.

In the cooking appliance according to an embodiment of the present disclosure, a height and a length of the door gap can be determined considering at least one of heat or electromagnetic waves used to heat the load in the cooking chamber.

In the cooking appliance according to an embodiment of the present disclosure, the choke can include a choke piece that has at least one surface protruding to be exposed to the cooking chamber, form the door gap through a first bent portion, and accommodate the shielding member through second to fourth bent portions.

In the cooking appliance according to an embodiment of the present disclosure, the choke cover can be formed of an elastic material, can be disposed between the fourth bent portion of the choke piece and one surface of the front panel, and can be in contact with one surface of the shielding member to support the shielding member.

In the cooking appliance according to an embodiment of the present disclosure, a width between the fourth bent portion of the choke piece and one surface of the front panel can be smaller than the height of the door gap.

In the cooking appliance according to an embodiment of the present disclosure, the choke can further include a first choke base that is disposed between an outer circumferential surface of the choke piece, an outer surface of the choke cover, and a cover of the door, and has a space to receive and shield at least one of heat or electromagnetic waves passing through the choke cover.

In the cooking appliance according to an embodiment of the present disclosure, the first choke base can include a plurality of bent portions and can be formed to have an arbitrary angle such that heat and electromagnetic waves incident through the choke cover and the plurality of bent portions are reflected.

In the cooking appliance according to an embodiment of the present disclosure, the door can further include a second choke base that receives and shields at least one of heat or electromagnetic waves generated in the cooking chamber through glass disposed in front of the cooking chamber, and the second choke base can have a space formed by a plurality of bent portions to induce and reflect at least one of heat or electromagnetic waves incident on the space defined therein.

In the cooking appliance according to an embodiment of the present disclosure, the first choke base can be in contact with at least a portion of the second choke base.

In the cooking appliance according to an embodiment of the present disclosure, a periodic structure of the choke can be designed as a slat structure in which grooves are formed at regular intervals, and a length of the choke and a width of the slat can be modified according to a frequency of the electromagnetic waves.

A cooking appliance according to an embodiment of the present disclosure can include a cooking chamber where a load is located, a front panel located at one end of the cooking chamber and having a bent portion, and a door that shields heat and electromagnetic waves. The door can include a cover assembly door including a handle, an inner portion including a mesh plate for electromagnetic wave shielding at a rear surface of the cover assembly door, a frame assembly door including a choke structure for shielding electromagnetic waves on a rear surface of inner glass of a glass structure that is mounted on a rear surface of the inner portion and blocks heat, a gasket packing that is mounted on a rear surface of the frame assembly door and shields heat and electromagnetic wave leakage when the door is closed, and a choke cover that covers the gasket packing and has a slat shape.

### BRIEF DESCRIPTION OF THE DRAWINGS

The above and other objects, features, and advantages of the present disclosure will become more apparent to those of ordinary skill in the art by describing example embodiments thereof in detail with reference to the attached drawings, which are briefly described below.

FIG. 1 is a perspective view of a cooking appliance according to an embodiment of the present disclosure.

FIGS. 2 to 4 are control block diagrams of a cooking appliance according to an embodiment of the present disclosure.

FIG. 5 is a cross-sectional view of a cooking appliance according to an embodiment of the present disclosure.

FIG. 6, including parts (a) and (b), is a configuration diagram of a cooking chamber according to an embodiment of the present disclosure.

FIG. 7 is a diagram illustrating a door choke structure according to an embodiment of the present disclosure.

FIG. 8 is a diagram illustrating a door choke structure according to an embodiment of the present disclosure.

FIG. 9 is a diagram illustrating a front panel according to an embodiment of the present disclosure.

FIG. 10 is a diagram illustrating a slat according to an embodiment of the present disclosure.

FIGS. 11 and 12 are diagrams for describing a door structure or configuration according to an embodiment of the present disclosure.

### DETAILED DESCRIPTION OF THE EMBODIMENTS

Hereinafter, embodiments of the present disclosure will be described in detail with reference to the accompanying drawings. Throughout the drawings, the same reference numerals are used to indicate the same or similar components.

The features of various embodiments of the present disclosure can be partially or entirely coupled to or combined with each other and can be interlocked and operated in technically various ways, and the embodiments can be carried out independently of or in association with each other.

Hereinafter, a cooking appliance according to an embodiment of the present disclosure will be described.

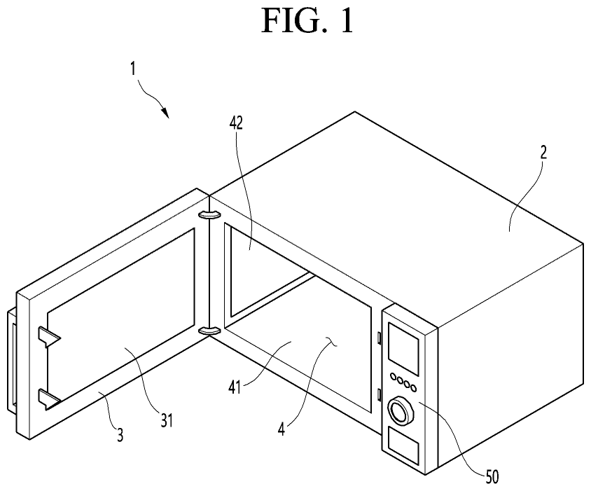

FIG. 1 is a perspective view of a cooking appliance 1 according to an embodiment of the present disclosure.

The cooking appliance 1 according to an embodiment of the present disclosure can include a housing 2 and a door 3 connected to the housing 2.

A cavity 4 can be formed in the housing 2. The cavity 4 can be a cooking chamber. The cavity 4 can be a cooking space where a load, that is, an object to be heated, is placed.

An input interface 50 can be formed on the outer surface of the housing 2. The input interface 50 can receive a user input for manipulating the cooking appliance 1.

The cavity 4 can be opened or closed by the door 3. The door 3 can be attached to the front portion of the housing 2. The door 3 can open and close the cavity 4.

A window 31 can be formed in the door 3. The user can check the inside of the cavity 4 through the window 31 when the cavity 4 is closed. The window 31 can include a window unit and a shielding unit.

The window unit can be formed of a transparent or a translucent material. The user can see the inside of the cavity 4 through the window unit.

The shielding unit can be mounted on the inner surface of the window unit. The shielding unit can block radio frequency (RF) from the cavity 4 from leaking out of the cooking appliance 1 through the door 3.

The shielding unit can be a wire mesh. A plurality of shielding holes can be defined in the shielding unit. The user can see the inside of the cavity 4 through the shielding hole, and RF does not pass through the shielding holes.

The cooking appliance according to an embodiment of the present disclosure can be an RF combination cooking appliance using RF heating, but the present disclosure is not limited thereto. Meanwhile, the RF combination cooking appliance can be an RF combination oven.

When cooking or defrosting the load, the cooking appliance according to the present disclosure can sense the load through at least one sensor, monitor sensing data in real time, and automatically control the operation of the cooking appliance.

The load can be food or an object to be heated, which is located within the cooking appliance and is heated or cooked by RF.

The at least one sensor can include a probe that is inserted into the load to acquire temperature data inside the load, an image sensor that acquires an image of the outer surface of the load, or a combination thereof. The image sensor can include a camera sensor. The cooking appliance can acquire, from the image of the outer surface of the load, data about the degree of searing of the outer surface of the load due to heating or cooking, that is, a searing value or brightness.

The cooking appliance 1 automatically ends cooking for the load when a set temperature is reached.

The cooking appliance 1 according to the present disclosure can not have a plate (e.g., a turntable) that assists uniform heating through the rotation of the load. The cooking appliance 1 can include at least one antenna for RF heating. However, the location or RF output direction of the at least one antenna in the cooking appliance 1 can be fixed. Therefore, since the load does not rotate in the cooking appliance 1, uniform heating is not easy.

Meanwhile, the cooking appliance 1 can calculate S11 (reflected wave/incident wave) through frequency scan and can heat the load by storing only the frequency that satisfies preset criteria, but accuracy can be low.

The cooking appliance 1 according to the present disclosure can collect and monitor sensing data about the load in real time by using at least one sensor (e.g., a temperature sensor such as a probe and/or an image sensor including a camera). As described above, the sensing data about the load can be data about the internal temperature or external cooking level of the load.

The cooking appliance 1 can monitor temperature data for a specific location or a plurality of locations of the load in real time by using at least one sensor.

The cooking appliance 1 can variably control the RF frequency and output based on the temperature data for the load monitored in real time, external shearing value (e.g., brightness) of the load, etc. In this manner, the cooking appliance 1 according to the present disclosure can be more efficient than the conventional cooking appliance and can accurately and uniformly heat the load.

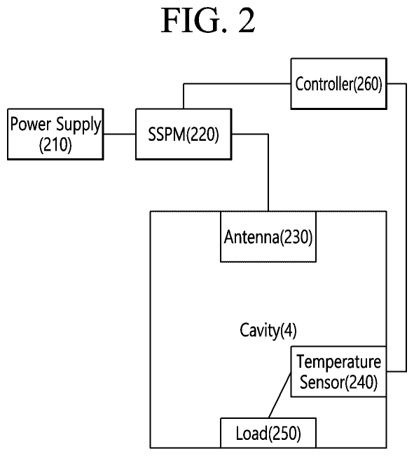

FIGS. 2 to 4 are control block diagrams of the cooking appliance 1 according to an embodiment of the present disclosure.

Referring to FIG. 2, the cooking appliance 1 can be configured to include a power supply 210, a solid-state power modulator (SSPM) 220, an antenna 230, a temperature sensor 240, and controller 260.

The power supply 210 can supply power such that the SSPM 220 operates. The power supply 210 can be a direct current (DC) power supply device.

The SSPM 220 can generate a desired heating frequency and RF output.

The RF output generated from the SSPM 220 can simultaneously penetrate through and directly heat the outside and inside of the load. Therefore, the temperature state of the load can be quickly controlled according to the RF output generated from the SSPM 220.

The cooking appliance 1 can heat food by oscillating one or more RF outputs from the SSPM 220, transmitting the RF outputs through a transmission line, and radiating the RF outputs to one or more multiple antennas inside the cooking chamber 4. That is, the cooking appliance 1 can perform accelerated heating control on the state of the load (e.g., temperature, etc.) by variably controlling the RF output oscillated from the SSPM 220.

Also, the SSPM 220 can be configured to include at least one of a signal generator configured to generate an RF signal, a signal intensity controller configured to control the frequency output generated by the signal generator, a phase controller configured to change the phase of the signal whose intensity is controlled by the signal intensity controller, a signal amplifier configured to amplify the controlled phase signal, a DC power supply configured to supply power necessary for signal amplification, a signal output detector configured to detect the output in which the signal amplified by the signal amplifier is radiated in a forward direction and the output in the reverse direction in which the signal is reflected and returned, a signal transmitter configured to radiate the amplified signal from a heater cooking chamber 4, a protection circuit configured to protect important core elements and circuits from the output coming in the reverse direction due to reflected waves, or an integrated controller configured to generate and control the RF frequency. However, not all of the listed components can be required.

The SSPM 220 can implement one or more multiple RF output oscillator circuits into one integrated circuit and can generate and vary the RF frequency signal by controlling the signal generator through the integrated controller located inside the SSPM 220. Additionally, the signals generated by the signal generator can be applied to the signal intensity controller to vary the output of the RF signal. The phase of the signal applied from the signal intensity controller can be changed in the phase controller by the integrated controller.

The output signal amplified by the signal amplifier of the SSPM 220 can be radiated from the radiation antenna 230 of the signal transmitter to the cooking chamber 4. The forward and reverse outputs of the radiated RF signal can be detected by the signal transmitter. The heating state (temperature) of the load can be controlled by controlling the frequency, output, phase, etc. by comparing and analyzing the detected signals in the integrated controller. Additionally, the signal transmitter can protect the internal circuit from signals that are reflected inside the SSPM 220 and output in the reverse direction.

The antenna 230 can radiate the RF output generated by the SSPM 220 to the load 250 located in the cooking chamber (e.g., the cavity 4) through the transmission line.

The temperature sensor 240 can be inserted into the load 250 to measure the temperature inside the load 250.

The controller 260 can generally control the operation of the cooking appliance 1. The controller 260 can monitor temperature data measured for the load 250 by the temperature sensor 240 and can control the SSPM 220 to variably control the frequency and RF output.

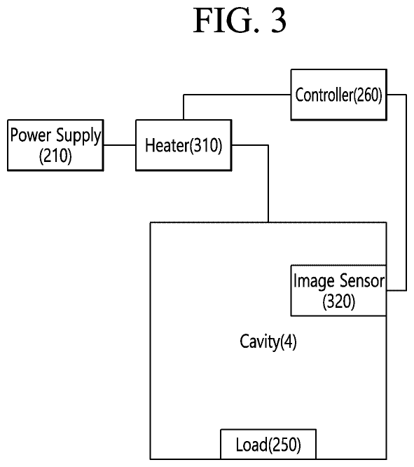

Referring to FIG. 3, the cooking appliance 1 can be configured to include a power supply 210, a heater 310, an image sensor 320, and a controller 260.

The power supply 210 can supply power such that the heater 310 operates. The power supply 210 can be a DC power supply device.

The heater 310 can generate heat for heating the load 250.

The image sensor 320 can acquire an image of the load 250 located within the cavity 4.

The controller 260 can acquire a brightness value for the outer surface of the load 250 from the image acquired by the image sensor 320, can control the heater 310 by monitoring the load 250, can variably control the output of the heater 310.

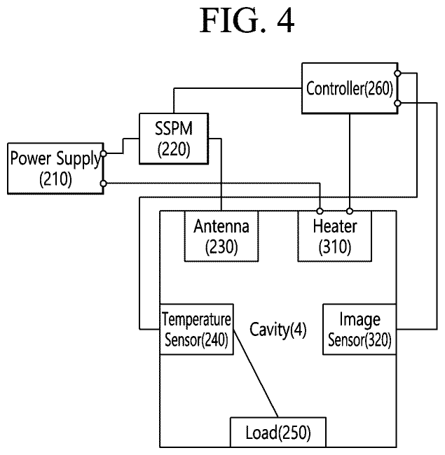

Referring to FIG. 4, the cooking appliance 1 can be configured to include a power supply 210, an SSPM 220, an antenna 230, a temperature sensor 240, a heater 310, an image sensor 320, and a controller 260.

FIG. 4 can be a combination of FIGS. 2 and 3. Therefore, the description of FIGS. 2 and 3 are equally applied to each component of FIG. 4, and redundant descriptions thereof are omitted.

However, since the function of the controller 260 is a combination of FIGS. 2 and 3, it will be described separately and can be as follows.

The controller 260 can monitor the load 250 by activating one or more of the temperature sensor 240 and the image sensor 320 and acquiring sensing data therefrom.

The controller 260 can control both the temperature sensor 240 and the image sensor 320 to be activated. In this case, the activation can be performed simultaneously or sequentially at intervals. In the latter case, for example, the controller 260 can activate the image sensor 320, and then, can further determine and control whether to activate the temperature sensor 240, based on the image analysis result acquired through the image sensor 320. The same is applied to the opposite case.

In FIGS. 2 and 4, only one SSPM 220 is illustrated, but a plurality of SSPMs 220 (e.g., for low frequency bands, for high frequency bands, etc.) can be provided according to the RF output or frequency band.

In FIGS. 2 and 4, only one antenna 230 is illustrated, but a plurality of antennas can be provided in the cavity 4. At this time, each antenna can be disposed at an appropriate position in consideration of the radiation direction or radiation angle such that the RF output generated by the SSPM 220 is uniformly radiated to the load 250.

According to embodiments, considering at least one of the size, shape, type, type, etc. of the load 250 to be placed in the cavity 4, at least one antenna 230 can be movable rather than fixed in position within the cavity 4, such that the RF output is well radiated to the load 250.

In FIGS. 3 and 4, only one heater 310 is illustrated, but a plurality of heaters, such as one heater 310 at the top of the cavity 4 and one heater 310 at the bottom of the cavity 4, can be provided. According to embodiments, the heater can be further provided on the side of the cavity 4.

The present disclosure relates to an electromagnetic wave-heat combination heating cooking appliance including an RF frequency heater and discloses a door structure including a shielding structure that prevents heat and electromagnetic waves generated in the cooking chamber from leaking out of the door.

The cooking appliance 1 is a product that cooks the load by using electromagnetic waves (RF) and/or high temperature heat through the SSPM 220 and/or the heater 310. However, problems can occur when high-temperature heat leaks out of the cooking appliance 1. Therefore, in the cooking appliance 1 according to the present disclosure, a component that prevents not only heat but also electromagnetic waves from escaping to the outside, that is, out of the cooking chamber, that is, a shielding member (e.g., a gasket) can be mounted between the door or the front surface of the cooking chamber (e.g., a front panel). At this time, the shielding member can be in contact with at least one surface of the door or the front panel.

However, this structure may cause a problem. For example, the door gap of the cooking appliance 1 increases compared to a conventional microwave oven. Typically, the door gap has increased to at least three times that of a microwave oven (e.g., 1.0 mm or less for a microwave oven, and 3.0 mm or more for an oven). In other words, when a door choke structure employed in a conventional microwave oven is used in the cooking appliance 1 according to the present disclosure, it may be difficult to adequately shield electromagnetic wave leakage.

Therefore, in the present disclosure, electromagnetic wave leakage can be primarily shielded by applying a metal mesh structure to the outside of the heat shielding component, that is, the gasket, which is one of the factors causing the increase in the door gap. The present disclosure is not limited to the metal mesh structure outside the gasket.

In addition, in the present disclosure, additional shielding can be achieved through a door choke structure that includes a door frame including a choke and a choke cover according to the present disclosure, which will be described later.

Meanwhile, thermal damage to the choke cover can be prevented by preventing high-temperature heat in the cooking chamber from being emitted by the heat shielding gasket.

As described above, the present disclosure discloses a door choke that prevents electromagnetic waves from leaking out of the door in a built-in combination oven having a frequency heater. In the case of built-in combination cooking appliances compared to conventional microwave ovens, the door gap is 2-3 times larger. Accordingly, a plurality of door chokes have been used to reliably shield electromagnetic wave leakage. However, when using the plurality of door chokes, the door becomes thicker than necessary or the structure or composition of the door becomes complicated, which inevitably causes limitations in the design of the cooking appliance as well as difficult manufacturing processes and size management.

Hereinafter, in the present disclosure, one door choke (e.g., a single door choke) can be implemented in the door frame to solve the above problems.

In the present disclosure, in order to supplement or further improve the shielding performance according to the single door choke, a gasket used for heat shielding can be utilized. That is, the present disclosure aims to change the structure of the gasket while using a single door choke such that heat shielding and electromagnetic wave shielding are achieved together.

In the present disclosure, a metal mesh such as STS can be added to a gasket made of glass fiber on the outermost surface of a door. Accordingly, in the present disclosure, the structure of the gasket has a metal-to-metal structure, such that both heat shielding and electromagnetic wave leakage shielding can be performed.

Meanwhile, in the present disclosure, since the door gap increases due to the seating structure of the gasket, the front door frame can protrude into the cooking chamber to form a gap with the wall of the cooking chamber. In the present disclosure, heat and electromagnetic wave leakage that have occurred only through the gasket can be primarily shielded through this gap.

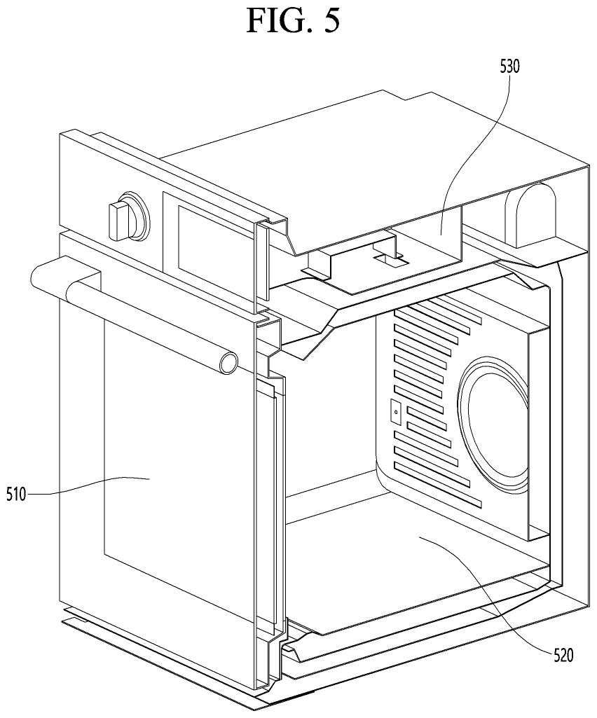

FIG. 5 is a cross-sectional view of the cooking appliance 1 according to an embodiment of the present disclosure.

Referring to FIG. 5, the cooking appliance 1 can include a door 510, a cooking chamber 520, and an electronic component chamber 530.

The door 510 can be configured to include a choke/porous mesh for electromagnetic wave shielding and glass/gasket for heat insulation.

The door 510 can be configured to reflect a shielding structure such that not only electromagnetic waves radiated from the electronic component chamber 530 to the load of the cooking chamber 520 but also heat generated by the heater do not leak out to the outside.

Meanwhile, the door 510 can include a window made of transparent glass such as ceramic glass. The window can be implemented in the form of a mesh plate (a porous mesh).

The cooking chamber 520 can be configured to include an antenna for heating the load, a top heater, and a convection device.

The cooking chamber 520 can have a shape that reflects an RF-compatible structure. The cooking chamber 520 can include a convection portion, a broil heater, an antenna, and at least one sensor.

The convection portion can include a convection cover and a motor. This convection portion can be mounted inside the cooking chamber or have a wide cover type chamber structure. Meanwhile, in the convection portion, a mesh for shielding the fan and the motor can be applied. However, the present disclosure is not limited thereto.

The broil heater can be controlled through a camera.

The antenna can be controlled through a voltage standing wave ratio (VSWR), a temperature detection sensor, etc.

The electronic component chamber 530 can be configured to include an RF generator, a heating source controller, cooling and power, etc.

The electronic component chamber 530 can include a control circuit printed circuit board (PCB) and RF major components (particularly cooling-related components) such as an SSPM/switched-mode power supply (SMPS) and RF feeding unit, a heat sinks, and a fan.

However, according to embodiments, the configuration or structure of FIG. 5 can be different from that illustrated herein.

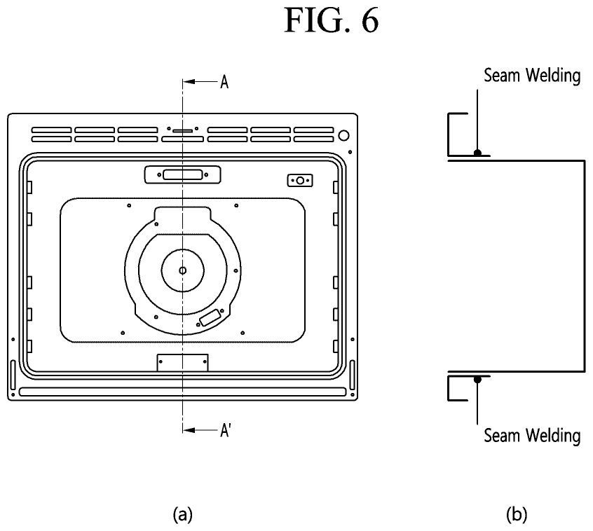

FIG. 6 is a configuration diagram of the cooking chamber 520 according to an embodiment of the present disclosure.

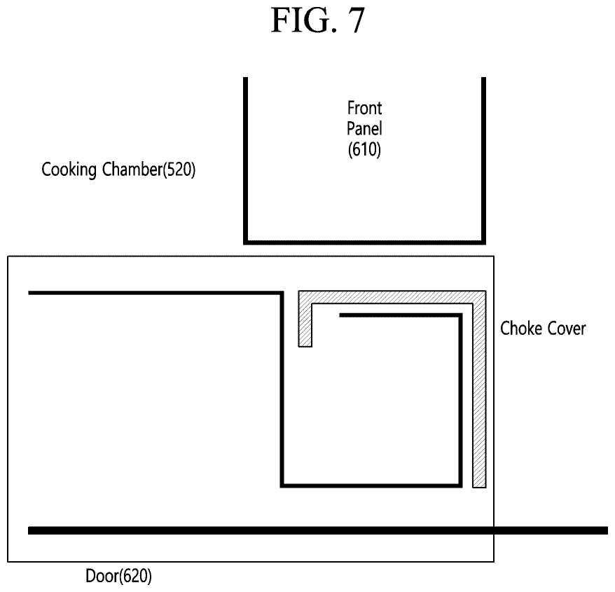

FIG. 7 is a diagram illustrating the door choke structure according to an embodiment of the present disclosure.

Part (a) of FIG. 6 is a view of the cooking appliance 1 when viewed from the front.

Part (b) of FIG. 6 is a cross-sectional view when viewed from A-A′ in FIG. (a) of FIG. 6.

Referring to part (b) of FIG. 6, the cooking chamber 520 can differ depending on the manufacturing method, but can largely include a front panel facing the door and the top, bottom, side, and back surfaces of the cooking chamber. Meanwhile, in the case of the built-in cooking appliance, the front panel has an opening in the front of the cooking chamber and can have a bent shape (grille) for fitting and fixing a drawer.

Referring to part (b) of FIG. 6, seam welding can be performed between the front and the inner plate. However, the present disclosure is not limited thereto.

The door choke structure is described below with reference to FIG. 7.

The door choke can be configured to shield electromagnetic waves (possibly heat).

The door choke can operate as an LC filter within a desired frequency band by a front panel 610 of the cooking chamber 520 and a door choke structure of a door 620 facing the front panel 610.

Accordingly, even if a gap exists between the door 620 and the front panel 610 when the door is closed, the door choke has an impedance of zero within a given electromagnetic wave band, thereby allowing electromagnetic waves to be reflected without leaking to the outside of the cooking appliance 1.

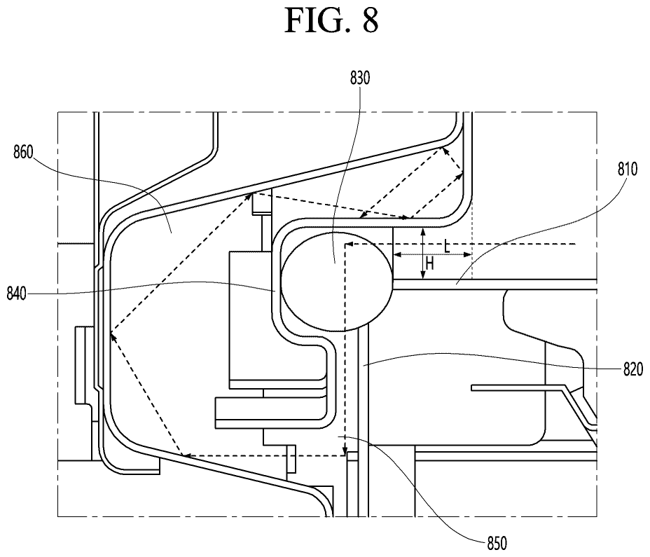

FIG. 8 is a diagram illustrating a door choke structure according to an embodiment of the present disclosure.

The cooking appliance according to an embodiment of the present disclosure can include a cooking chamber 520 where a load is located, a front panel 810 located at one end of the cooking chamber 520 and whose portion is bent, and a door that shields heat and electromagnetic waves.

The door can include a door frame including a single door choke. The door can include glass. The door can include a plate including a porous mesh. The door can include a choke cover.

The door can include or be combined with a shielding member, that is, a gasket 830. For convenience of explanation, the gasket is located between the front panel and the door and is described as being mounted on the door.

The gasket according to the present disclosure can be disposed between the front panel and the door and can shield heat/electromagnetic waves leaking from the cooking chamber toward the outside of the cooking appliance 1.

A metal mesh can be added to the gasket according to the present disclosure. At this time, the metal mesh can surround the entire surface or outer surface while facing at least the cooking chamber. In this manner, the gasket according to the present disclosure can perform both the heat shielding function and the electromagnetic wave shielding function. In addition, this metal mesh can also perform the function of preventing overheating of the choke cover, which will be described later.

In the present disclosure, the gasket 830 can have a circular (or oval) shape, but is not limited thereto.

The gasket according to the present disclosure can have a perimeter according to a predefined radius (or diameter).

The gasket 830 according to the present disclosure can be a member formed of an elastic material. As illustrated in FIG. 8, a portion where one end of the gasket is in contact with the front panel can be in complete contact with the front panel due to pressure. Therefore, there can be no gap, thereby preventing heat from leaking. Meanwhile, according to embodiments, the front panel, not the gasket, is a member of an elastic material. As described above, the shape is deformed by pressure to accommodate the gasket and there is no gap therebetween, thereby preventing heat from the cooking chamber from leaking to the outside. In addition to the heat described above, electromagnetic waves can also be shielded in the same way when the metal mesh is mounted on the gasket.

The door choke structure according to the present disclosure will be described with reference to FIG. 8.

Referring to FIG. 8, the choke structure can extend a portion facing the choke from the front panel to the inner wall of the cooking chamber in order to minimize electromagnetic wave leakage and increase the cover bandwidth.

As described above, the metal-to-metal structure can be formed between the choke piece and the front panel/the interior wall of the cooking chamber by increasing the choke structure according to the present disclosure and applying a structure that surrounds the outside of the gasket used for heat shielding with the metal mesh, thereby further improving electromagnetic wave shielding performance.

Meanwhile, in the present disclosure, a choke cover made of heat-resistant rubber can be configured for protecting the appearance of the choke.

As described above, the door frame can protrude toward the cooking chamber to form a door gap.

The door frame can protrude toward the cooking chamber 520 by a length smaller than the circumference of the gasket. The door frame can protrude toward the cooking chamber 520 by a length greater than the radius of the gasket. The door frame can protrude toward the cooking chamber 520 by a length larger than the radius of the gasket and smaller than the circumference.

The height and length of the door gap can be determined considering at least one of heat or electromagnetic waves used to heat the load in the cooking chamber.

The door gap can be smaller than the diameter of the gasket and can be equal to or larger than the radius.

The choke piece can be located on the front side of the front panel.

The choke piece can be formed along the outer circumferential surface of the gasket. In this manner, the choke piece can support the gasket. The choke piece can accommodate the gasket and apply pressure to the gasket in the direction of the cooking chamber to minimize the gap between the gasket and the front panel, thereby contributing to blocking heat and electromagnetic waves.

The choke piece 840 can have a plurality of bent portions. The number of bent portions of the choke piece can be determined according to the shape of the gasket.

In FIG. 8, the surface of the choke piece accommodating the gasket may not be in complete contact with the gasket 830 on all surfaces.

Referring to FIG. 8, the choke piece space where the gasket 830 is accommodated, rather than the portion of the gasket exposed to the cooking chamber 520, accommodates and supports the entire gasket, but it can be sufficient if it is in contact with one surface (or one point) of the gasket. As described above, this can be to apply pressure through the choke piece such that the gasket comes into contact with the front panel formed toward the cooking chamber, that is, on the inner wall of the cooking chamber.

In the cooking appliance 1 according to the present disclosure, a choke base with a predetermined space can be formed on the outer circumferential surface of the choke cover and the choke piece.

The choke base can include a plurality of bent portions.

The choke base can have a shape that becomes narrower in the opposite direction rather than in the direction of the cooking chamber 520. To this end, a plurality of bent portions can be formed in the choke base.

At least one of the size, volume, or shape of the choke base space can vary depending on the operating frequency of the cooking appliance 1.

The door can have a choke structure shape determined depending on the frequency of the electromagnetic waves through the single door choke.

In the present disclosure, heat and electromagnetic waves can be primarily blocked through the gasket, heat and electromagnetic waves can be secondarily blocked through the choke cover, and heat and electromagnetic waves can be tertiarily blocked through the choke base.

The choke can include a choke piece that has at least one surface protruding to be exposed to the cooking chamber, forms the door gap through a first bent portion, and accommodates a shielding member through second to fourth bent portions.

The choke cover can be formed of an elastic material. The choke cover can be disposed between the fourth bent portion of the choke piece and one surface of the front panel. The choke cover can be in contact with one surface of the shielding member to support the shielding member.

The width between the fourth bent portion of the choke piece and one surface of the front panel can be smaller than the height of the door gap.

The choke can further include a first choke base that is disposed between the outer circumferential surface of the choke piece, the outer surface of the choke cover, and the cover of the door, and has a space to receive and shield at least one of heat or electromagnetic waves passing through the choke cover.

The first choke base 850 can include a plurality of bent portions. The first choke base can be formed to have an arbitrary angle such that heat and electromagnetic waves incident through the choke cover and the plurality of bent portions are reflected.

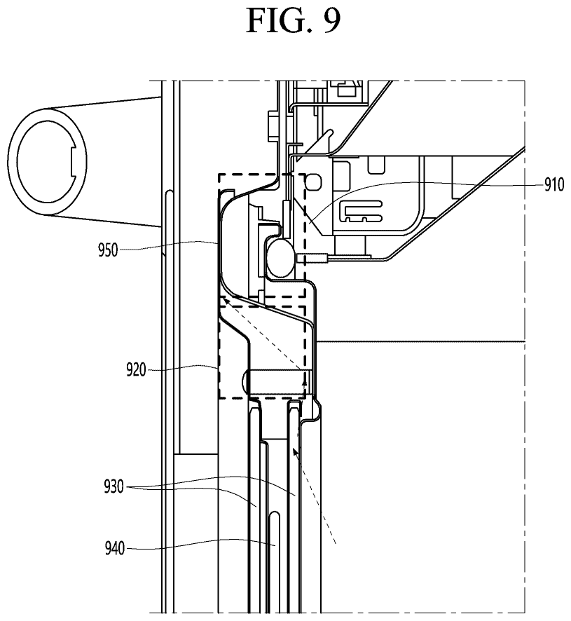

FIG. 9 is a diagram illustrating a front panel according to an embodiment of the present disclosure.

The door can further include a second choke base 920 that receives and shields at least one of heat or electromagnetic waves generated in the cooking chamber through glass disposed in the front of the cooking chamber.

The second choke base 920 can have a space formed by a plurality of bent portions to induce and reflect at least one of heat or electromagnetic waves incident on the space defined therein.

Referring to FIG. 9, the first choke base 950 can be in contact with at least a portion of the second choke base 920. For example, the outer surface of the first choke base 950 can be the inner surface of the second choke base 920.

Unlike FIG. 8, in FIG. 9, the door can include a porous mesh cover, glass, a choke base, a platform assembly, and a porous mesh cover.

In FIG. 9, the gasket can be in contact with the float panel on at least two sides. As described above, a choke piece having a plurality of bent portions can be formed on the outer circumferential surface of the gasket. However, unlike as illustrated in FIG. 8, the choke piece can be directly exposed to the cooking chamber. In other words, the choke piece can directly reflect electromagnetic waves. Heat can be blocked from leaking through the gasket.

Meanwhile, as illustrated in FIG. 9, electromagnetic waves (and heat) generated in the cooking chamber can be guided in a predetermined direction through the glass when incident.

Electromagnetic waves induced in this way can be absorbed or reflected through the porous mesh cover and glass.

Meanwhile, the incident electromagnetic waves (and heat) enter through a path guided by the glass, but can be further induced according to the choke base with the bent portions.

Electromagnetic waves further induced by the choke base can enter the gap formed by the platform assembly and the porous mesh cover and can be reflected back. At this time, an elastic metal can be inserted into the gap between the platform assembly and the porous mesh cover. Accordingly, the gap described above can be arbitrarily adjusted.

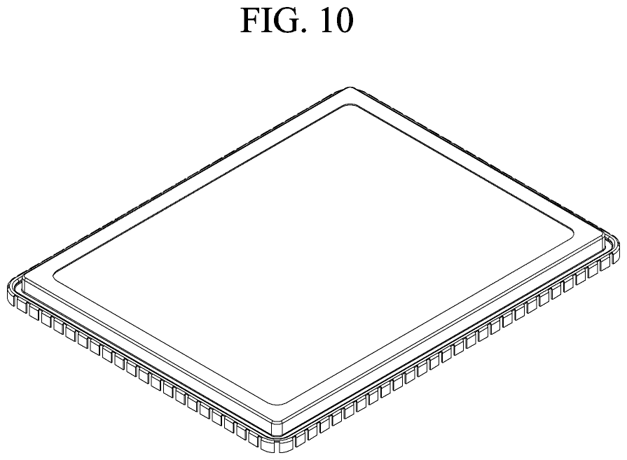

FIG. 10 is a diagram illustrating a slat according to an embodiment of the present disclosure.

The periodic structure of the choke according to the present disclosure can be designed as a slat structure in which grooves are formed at regular intervals, as illustrated in FIG. 10. However, the present disclosure is not limited thereto. That is, spacing, grooves, etc. can be designed differently from those illustrated in the drawings.

The length of the choke can be modified depending on the operating frequency of the cooking appliance 1.

The width of the slat can be modified depending on the operating frequency of the cooking appliance 1.

The length of the choke and the width of the slat can be modified depending on the operating frequency of the cooking appliance 1.

The operating frequency of the cooking appliance 1 can be modified depending on the length of the choke.

The operating frequency of the cooking appliance 1 can be modified depending on the width of the slat.

The operating frequency of the cooking appliance 1 can be modified depending on the length of the choke and the width of the slat.

The choke can be miniaturized according to the present disclosure, and the thickness of the cooking appliance 1 in which electromagnetic waves are additionally used as a heat source can be reduced through performance stability.

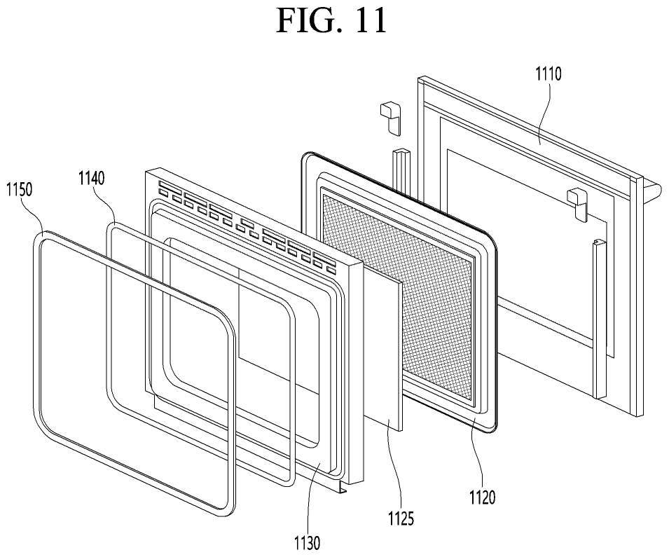

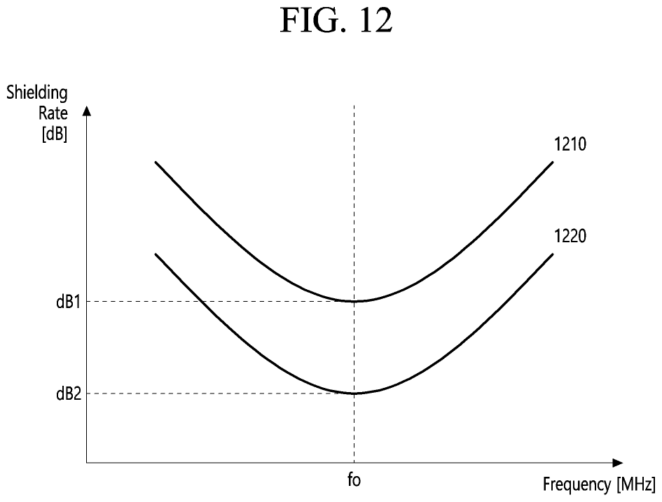

FIGS. 11 and 12 are diagrams for describing the door structure or configuration according to an embodiment of the present disclosure.

FIG. 11 illustrates an example of the structure or configuration of the door according to an embodiment of the present disclosure.

Referring to FIG. 11, the door according to the present disclosure can provide both heat shielding and electromagnetic wave shielding even though the same components and space as those of the conventional cooking appliance are used to maintain the door thickness and cooking chamber capacity of the conventional cooking appliance.

The cooking appliance 1 can include a cooking chamber where a load is located, a front panel located at one end of the cooking chamber, and having a bent portion, and a door that shields heat and electromagnetic waves.

In particular, referring to FIG. 11, the door can include a cover assembly door 1110 including a handle.

The door can include a rocker assembly formed at one end of the cover assembly door.

The door can include an inner portion 1120 including a mesh plate for electromagnetic wave shielding at the rear surface of the cover assembly door.

The door can include an inner glass 1125 of a glass (e.g., double-layer) structure that is mounted on the rear surface of the inner portion and blocks heat.

The door can include a frame assembly door 1130 including a choke structure for electromagnetic wave shielding on the rear surface of the inner glass.

The door can include a gasket packing 1140 that is mounted on the rear surface of the frame assembly door 1130 and shields heat and electromagnetic wave leakage when the door is closed.

The door can include a choke cover 1150 that covers the gasket packing 1140 and has a slat shape.

The door can be configured to include a plurality of the components described above.

Referring to FIG. 12, it can be seen that the choke has the highest shielding performance at the design frequency depending on the frequency characteristics of the choke and has characteristics that decrease left and right with respect to the frequency (fo).

The combination cooking appliance with electromagnetic wave heating according to the present disclosure is described as including the front panel with the curved left and right outer edges having a structure suitable for the size of the drawer, the cooking chamber attached thereto, and the door.

The door can be configured to include a door frame including a choke, glass, a plate including a porous mesh, a choke cover, a gasket, etc., and can shield heat and electromagnetic waves together (or simultaneously).

According to the present disclosure, one choke for preventing electromagnetic wave leakage, that is, a single choke, is configured such that the front panel and the inner wall of the cooking chamber face each other to secure maximum shielding performance in a limited space.

To this end, in the present disclosure, the structure bent at least once and the slot structure can be applied to form the choke in a limited space.

The periodic slots may not be applied to the side not covered by the choke cover. The portion where the periodic slots are applied and the choke opening can be covered with the choke cover.

Heat and electromagnetic wave leakage can be shielded by covering the outermost portion of the gasket, which is used to prevent heat leakage from the cooking chamber, with the metal mesh.

In addition, the choke cover made of high-temperature rubber can serve to primarily block heat at high temperatures to prevent damage caused by heat.

In the present disclosure, since the end face of the gasket is in contact with the front panel, the choke cover does not come into contact with the high temperature front panel, thereby preventing thermal damage due to contact.

In the present disclosure, the gasket and the choke cover can be seated on the frame assembly toward the inside of the cooking chamber. Meanwhile, the glass for heat blocking can be placed outside the cooking chamber, and the porous mesh cover can be placed behind the glass to shield electromagnetic wave leakage.

Therefore, according to the present disclosure, even if electromagnetic waves pass through the glass, electromagnetic wave leakage is shielded by the porous mesh. Since leakage can occur in the gap between the frame assembly and the porous mesh cover, electromagnetic wave leakage into the gap can be additionally shielded by inserting an elastic metal therebetween.

In the present disclosure, shielding can refer to preventing electromagnetic waves from leaking to the outside of the cooking appliance 1 through reflection, absorption, etc.

According to at least one of various embodiments of the present disclosure, there is an effect of automatically controlling cooking by monitoring the load in real time.

According to at least one of various embodiments of the present disclosure, there is an effect of variably controlling the frequency and output of the heat source according to the load.

According to at least one of various embodiments of the present disclosure, there is an effect of enabling more accurate and uniform heating of the load.

In addition to the above-described effects, specific effects of the present disclosure will be described together while explaining specific details.

The above description is merely illustrative of the technical spirit of the present disclosure, and various modifications and changes can be made by those of ordinary skill in the art, without departing from the scope of the present disclosure.

Therefore, the embodiments disclosed in the present disclosure are not intended to limit the technical spirit of the present disclosure, but are intended to explain the technical spirit of the present disclosure. The scope of the technical spirit of the present disclosure is not limited by these embodiments.

The scope of the present disclosure should be interpreted by the appended claims, and all technical ideas within the scope equivalent thereto should be construed as falling within the scope of the present disclosure.

### DESCRIPTION OF SYMBOLS

1: cooking appliance
2: housing
3: door
4: cavity

What is claimed is:

1. A cooking appliance comprising:
a cooking chamber configured to receive a load to be heated;
a front panel disposed at one end of the cooking chamber and having a bent portion; and
a door configured to shield both heat and electromagnetic waves generated in the cooking chamber,
wherein the door includes a door frame including a choke and a choke cover,
wherein a shielding member is disposed between the front panel and the door, and
wherein the shielding member is in contact with at least one surface of the front panel and in contact with the door.

2. The cooking appliance of claim 1, wherein the door frame includes a door gap facing toward the cooking chamber.

3. The cooking appliance of claim 2, wherein the shielding member includes an elastic material,
wherein a cross section of the shielding member has a circular shape or a rounded shape, and
wherein an outer circumference of the shielding member overlaps with a metal mesh.

4. The cooking appliance of claim 2, wherein a height of the door gap and a length of the door gap are based on at least one of a size of the shielding member and an elasticity of the shielding member.

5. The cooking appliance of claim 2, wherein a height of the door gap and a length of the door gap is based on at least one of heat or electromagnetic waves used to heat the load in the cooking chamber.

6. The cooking appliance of claim 4, wherein the choke includes a choke piece having at least one protruding surface exposed to the cooking chamber,
wherein the at least one protruding surface of the choke piece forms the door gap based on a first bent portion of the choke piece, and
wherein the choke piece is configured to at least partially surround or accommodate the shielding member based on second, third and fourth bent portions of the choke piece.

7. The cooking appliance of claim 6, wherein the choke cover includes an elastic material,
wherein the choke cover is disposed between the fourth bent portion of the choke piece and one surface of the front panel, and
wherein the choke cover is in contact with one surface of the shielding member to support the shielding member.

8. The cooking appliance of claim 6, wherein a distance between the fourth bent portion of the choke piece and one surface of the front panel is smaller than the height of the door gap.

9. The cooking appliance of claim 6, wherein the choke further includes a first choke base disposed between or at least partially surrounded by an outer circumferential surface of the choke piece, an outer surface of the choke cover and a cover of the door, and
wherein first choke base has an empty space configured to receive and shield at least one of heat or electromagnetic waves passing through or passing by the choke cover.

10. The cooking appliance of claim 9, wherein the first choke base includes a plurality of bent portions formed at angles configured to reflect heat and electromagnetic waves incident through the choke cover.

11. The cooking appliance of claim 9, wherein the door further includes a second choke base configured to receive and shield at least one of heat or electromagnetic waves generated in the cooking chamber that pass through or by glass disposed in front of the cooking chamber, and
wherein the second choke base has an empty space formed by a plurality of bent portions configured to reflect at least one of the heat or the electromagnetic waves.

12. The cooking appliance of claim 11, wherein the first choke base is in contact with at least a portion of the second choke base.

13. The cooking appliance of claim 1, wherein a periodic structure of the choke is designed as a slat structure having grooves formed at regular intervals, and
wherein a length of the choke and a width of the slat structure are based on a frequency of the electromagnetic waves.

14. A cooking appliance comprising:
a cooking chamber configured to receive a load to be heated;
a front panel disposed at one end of the cooking chamber and having a bent portion; and
a door configured to shield heat and electromagnetic waves,
wherein the door includes:
a cover assembly door having a handle;
an inner portion including a mesh plate disposed at a rear surface of the cover assembly door;
a frame assembly door including a choke structure for shielding electromagnetic waves incident on a rear surface of a glass structure that is mounted on a rear surface of the inner portion;
a gasket packing mounted on a rear surface of the frame assembly door and configured to shield heat and electromagnetic wave leakage; and
a choke cover overlapping with the gasket packing, the choke cover having a slat shape.

15. A cooking appliance comprising:
a cooking chamber configured to receive a load to be heated;
a front panel disposed at an opening of the cooking chamber;
a door including a frame assembly having a choke structure;
a gasket disposed on a rear of the frame assembly; and
a choke cover overlapping with the gasket,
wherein the choke structure protrudes past an outer surface of the front panel and into the cooking chamber.

16. The cooking appliance of claim 15, wherein the choke structure includes a plurality of bent portions at least partially surrounding the gasket.

17. The cooking appliance of claim 15, wherein the choke structure includes a first choke base having a plurality of first bent portions configured to reflect electromagnetic waves that have passed through the gasket back towards the cooking chamber.

18. The cooking appliance of claim 17, wherein the choke structure includes a second choke base having a plurality of second bent portions configured to reflect electromagnetic waves that have passed through the door.

19. The cooking appliance of claim 18, wherein the second choke base is connected to the first choke base.

20. The cooking appliance of claim 15, wherein the choke cover has a slat shape including a plurality of slits formed at a same interval spacing.
